(19) United States
(12) Patent Application Publication
(10) Pub. No.: US 2024/0222156 A1
(43) Pub. Date: Jul. 4, 2024

(54) SUBSTRATE TREATING APPARATUS AND SEMICONDUCTOR MANUFACTURING EQUIPMENT INCLUDING THE SAME

(71) Applicant: SEMES CO., LTD., Chungcheongnam-do (KR)

(72) Inventors: Jong Seok SEO, Chungcheongnam-do (KR); Sun Sup LIM, Gyeonggi-do (KR)

(21) Appl. No.: 18/513,560

(22) Filed: Nov. 19, 2023

(30) Foreign Application Priority Data
Dec. 28, 2022 (KR) 10-2022-0186724

(51) Int. Cl. H01L 21/67; H01L 21/687

(52) U.S. Cl. CPC H01L 21/67069; H01L 21/67098; H01L 21/67167; H01L 21/67253; H01L 21/68707

(57) ABSTRACT

There are provided a substrate treating apparatus capable of controlling the internal airflow in a space when performing heat treatment on a substrate in the corresponding space and semiconductor manufacturing equipment including the substrate treating apparatus. The substrate treating apparatus includes: a heating plate heating a substrate; a cover module covering the top of the heating plate; an intake module introducing external air into an internal space formed by the cover module; and an exhaust module discharging the air introduced into the internal space to the outside, wherein at least one of the intake module and the exhaust module controls airflow in the internal space.

### CROSS-REFERENCE TO RELATED APPLICATION

This application claims priority from Korean Patent Application No. 10-2022-0186724 filed on Dec. 28, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a substrate treating apparatus and semiconductor manufacturing equipment including the same, and more particularly, to a substrate treating apparatus that performs heat treatment on a substrate and semiconductor manufacturing equipment including the substrate treating apparatus.

### 2. Description of the Related Art

Semiconductor manufacturing processes may be continuously carried out within semiconductor manufacturing equipment and may be classified into front-end processes and back-end processes. Here, the front-end processes refer to processes of forming circuit patterns on a wafer to complete a semiconductor chip, while the back-end processes refer to processes of evaluating the performance of a completed product obtained through the front-end processes.

The semiconductor manufacturing equipment can be installed within a semiconductor manufacturing plant called a fab. Wafers go through various processes such as deposition, photolithography, etching, ion implantation, cleaning, packaging, and inspection, sequentially moving to equipment where each process is performed to produce semiconductors.

Photolithography is a process for forming patterns on semiconductor substrates, and includes coating, exposure, and development processes. A bake process for heat-treating semiconductor substrates may be performed before or after the exposure process.

However, in a process chamber where the bake process takes place, the internal flow may act as a factor affecting process yield. Traditionally, there has not yet been a method to correct flow deviations, leading to the problem of uneven thickness in insulating films formed on semiconductor substrates.

### SUMMARY

Aspects of the present disclosure provide a substrate treating apparatus and semiconductor manufacturing equipment including the same that can control the internal flow with a space when performing heat treatment on a substrate in the space.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate treating apparatus includes: a heating plate heating a substrate; a cover module covering the top of the heating plate; an intake module introducing external air into an internal space formed by the cover module; and an exhaust module discharging the air introduced into the internal space to the outside, wherein at least one of the intake module and the exhaust module controls airflow in the internal space.

According to another aspect of the present disclosure, semiconductor manufacturing equipment includes: a plurality of process chambers of different types, wherein the plurality of process chambers include a first substrate treating apparatus that performs heat treatment on a substrate and a second substrate treating apparatus that performs a development process on the substrate, the first substrate treating apparatus includes a heating plate heating a substrate, a cover module covering the top of the heating plate, an intake module introducing external air into an internal space formed by the cover module, and an exhaust module discharging the air introduced into the internal space to the outside, and at least one of the intake module and the exhaust module controls airflow in the internal space.

According to another aspect of the present disclosure, a substrate treating apparatus includes: a heating plate heating a substrate; a cover module covering the top of the heating plate; an intake module introducing external air into an internal space formed by the cover module; an exhaust module discharging the air introduced into the internal space to the outside; and a gas concentration control module controlling a gas concentration in the internal space, wherein the intake module controls an inflow amount of air, the exhaust module controls an outflow amount of air, the intake module and the exhaust module control airflow in the internal space by controlling the inflow and outflow amounts of air independently, the intake module and the exhaust module control the airflow in the internal space when adjusting a thickness of an insulating film formed on the substrate, and the gas concentration control module controls the gas concentration in the internal space when controlling etch rate for the substrate.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a first exemplary schematic view illustrating the internal configuration of semiconductor manufacturing equipment including a substrate treating apparatus that performs heat treatment on a semiconductor substrate;

FIG. 2 is a second exemplary schematic view illustrating the internal configuration of the semiconductor manufacturing equipment including the substrate treating apparatus that performs heat treatment on a semiconductor substrate;

FIG. 3 is a third exemplary schematic view illustrating the internal configuration of the semiconductor manufacturing equipment including the substrate treating apparatus that performs heat treatment on a semiconductor substrate;

FIG. 4 is a plan view illustrating the internal configuration of a substrate treating apparatus that performs heat treatment on a semiconductor substrate;

FIG. 5 is a cross-sectional view of the substrate treating apparatus that performs heat treatment on a semiconductor substrate;

FIG. 6 is a first exemplary schematic view illustrating the internal configuration of a heating unit in the substrate treating apparatus for internal airflow control;

FIG. 7 is a second exemplary schematic view illustrating the internal structure of the heating unit in the substrate treating apparatus for internal airflow control;

FIG. 8 is a first exemplary schematic view illustrating an internal airflow control method of the heating unit of the substrate treating apparatus;

FIG. 9 is a second exemplary schematic view illustrating the internal airflow control method of the heating unit of the substrate treating apparatus;

FIG. 10 is a third exemplary schematic view illustrating the internal airflow control method of the heating unit of the substrate treating apparatus;

FIG. 11 is a first exemplary schematic view illustrating the arrangement structure of air exhaust holes of an intake module in the heating unit;

FIG. 12 is a second exemplary schematic view illustrating the arrangement structure of the air exhaust holes of the intake module in the heating unit;

FIG. 13 is a first exemplary schematic view illustrating a control method for exhaust modules within the heating unit;

FIG. 14 is a second exemplary schematic view illustrating the control method for the exhaust modules in the heating unit; and

FIG. 15 is an exemplary schematic view illustrating a gas concentration control module of the substrate treating apparatus.

### DETAILED DESCRIPTION

Embodiments of the present disclosure will hereinafter be described with reference to the attached drawings. The same reference numerals are used for the same components in the drawings, and redundant explanations of these will be omitted.

The present disclosure relates to a substrate treating apparatus that performs heat treatment on a semiconductor substrate and semiconductor manufacturing equipment including the same. When performing heat treatment on a semiconductor substrate, the substrate treating apparatus may control the internal flow within a space where the heat treatment is performed. As a result, fine thickness adjustment for insulating films can be enabled so that the insulating films can be formed on the semiconductor substrate to have a uniform thickness. Further details of the present disclosure will hereinafter be described in detail with reference to the accompanying drawings.

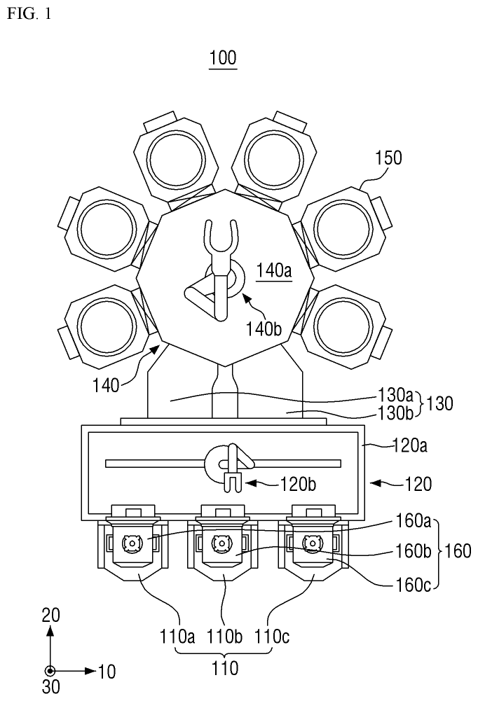

FIG. 1 is a first exemplary schematic view illustrating the internal configuration of semiconductor manufacturing equipment including a substrate treating apparatus that performs heat treatment on a semiconductor substrate. Referring to FIG. 1, semiconductor manufacturing equipment 100 may be configured to include load ports 110, an index module 120, load lock chambers 130, a transfer module 140, and process chambers 150.

The semiconductor manufacturing equipment 100 is a system for treating semiconductor substrates through various processes such as deposition, etching, cleaning, and heat treatment. For this purpose, the semiconductor manufacturing equipment 100 may be implemented as a multi-chamber substrate treating system including a plurality of process chambers 150 of the same type or different types, such as a chamber for performing a deposition process, a chamber for performing an etching process, a chamber for performing a cleaning process, and a chamber for performing a heat treatment process.

The load ports 110 are provided to accommodate containers 160 loaded with multiple semiconductor substrates. The containers 160 may be, for example, front opening unified pods (FOUPs).

The containers 160 may be loaded onto or unloaded from the load ports 110. Also, the semiconductor substrates stored in the containers 160 may be loaded onto or unloaded from the load ports 110.

Specifically, the containers 160 may be loaded onto or unloaded from the load ports 110 by a container transporting device. Specifically, the containers 160 may be loaded onto the load ports 110 by mounting the containers 160 transported by the container transporting device in the load ports 110. Similarly, the containers 160 may be unloaded from the load ports 110 by gripping the containers 160 placed on the load ports 110 with the container transporting device. Although not explicitly illustrated in FIG. 1, the container transporting device may be, for example, an overhead hoist transporter (OHT).

The semiconductor substrates may be loaded onto or unloaded from the containers 160 placed on the load ports 110 by a substrate transfer robot 120b. Once the containers 160 are placed on the load ports 110, the substrate transfer robot 120b may approach the load ports 110 and may retrieve the semiconductor substrates from the containers 160. In this manner, the unloading of the semiconductor substrates may be performed.

Once the treatment of the semiconductor substrates is complete within the process chambers 150, the substrate transfer robot 120b may retrieve remove the semiconductor substrates from the load lock chambers 130 and place them back onto the containers 160. In this manner, the loading of the semiconductor substrates may be performed.

A plurality of load ports 110 may be disposed in front of the index module 120. For example, three load ports 110, i.e., first, second, and third load ports 110a, 110b, and 110c, may be disposed in front of the index module 120.

When the load ports 110 are disposed in front of the index module 120, the containers 160 mounted on the load ports 110 may accommodate different types of items. For example, when three load ports 110, i.e., the first, second, and third load ports 110a, 110b, and 110c, are provided in front of the index module 120, a first container 160a on the first load port 110a to the far left may carry a wafer-type sensor, a second container 160b on the second load port 110b in the middle may carry substrates (or wafers), and a third container 160c on the third load port 110c to the far right may carry a consumable part such as a focus ring or an edge ring.

However, the present embodiment is not limited to this. Alternatively, the first, second, and third containers 160a, 160b, and 160c may all carry items of the same type. Yet alternatively, some of the first, second, and third containers 160a, 160b, and 160c may carry items of the same type, and the other containers may carry items of a different type.

The index module 120 is disposed between the load ports 110 and the load lock chambers 130 and interfaces the transfer of the semiconductor substrates between the containers 160 on the load ports 110 and the load lock chambers 130. For this purpose, the index module 120 may include a substrate transfer robot 120b within a module housing 120a. The substrate transfer robot 120b may operate in an atmospheric pressure environment, and at least one substrate transfer robot 120b may be provided within the module housing 120a.

Although not illustrated in FIG. 1, one or more buffer chambers may be provided within the index module 120. Untreated substrates may be temporarily stored in the buffer chambers before being transferred to the load lock chambers 130, and treated substrates may also be temporarily stored before being inserted into the containers 160 on the load ports 110. The buffer chambers may be provided on sidewalls that are not adjacent to either the load ports 110 or the load lock chambers 130, but the present disclosure is not limited thereto. Alternatively, the buffer chambers may be provided on sidewalls adjacent to the load lock chambers 130.

A front-end module (FEM) may be provided on sides of the load lock chambers 130. The FEM may include the load ports 110 and the index module 120 and may be implemented as an equipment FEM (EFEM) or a substrate FEM (SFEM).

Meanwhile, the first, second, and third load ports 110a, 110b, and 110c may be arranged in a horizontal direction (e.g., a first direction 10), but the present disclosure is not limited thereto. Alternatively, the first, second, and third load ports 110a, 110b, and 110c may be stacked in a vertical direction, in which case, the FEM may be configured as, for example, a vertically stacked EFEM.

The load lock chambers 130, which may also be referred to as buffer chambers, function as buffer chambers between the input and output ports of the semiconductor manufacturing equipment 100. Although not explicitly illustrated in FIG. 1, the load lock chambers 130 may include buffer stages where the semiconductor substrates temporarily stand by.

A plurality of load lock chambers 130 may be disposed between the index module 120 and the transfer module 140. For example, two load lock chambers, i.e., first and second load lock chambers 130a and 130b, may be disposed between the index module 120 and the transfer module 140.

The first and second load lock chambers 130a and 130b may be arranged in the horizontal direction (e.g., the first direction 10). In this case, the first and second load lock chambers 130a and 130b may be arranged in the same direction as the first, second, and third load ports 110a, 110b, and 110c and may be provided in a symmetrical single-layer structure aligned in a left-to-right direction. Here, the first direction 10 refers to a direction perpendicular to the arrangement direction (e.g., a second direction 20) of the index module 120 and the transfer module 140.

However, the present disclosure is not limited to this. Alternatively, the first and second load lock chambers 130a and 130b may also be arranged in the vertical direction (e.g., a third direction 30) between the index module 120 and the transfer module 140. In this case, the first and second load lock chambers 130a and 130b may be provided in a multi-layer structure aligned in the vertical direction. Here, the third direction 30 refers to a direction perpendicular to a plane including the arrangement direction (e.g., the first direction 10) of the first, second, and third load ports 110a, 110b, and 110c and the arrangement direction (e.g., the second direction 20) of the index module 120 and the transfer module 140 arrangement direction.

The first load lock chamber 130a may transfer the semiconductor substrates from the index module 120 to the transfer module 140, and the second load lock chamber 130b may transfer the semiconductor substrates from the transfer module 140 to the index module 120. However, the present disclosure is not limited to this. Alternatively, the first load lock chamber 130a may perform both the roles of transferring the semiconductor substrates from the transfer module 140 to the index module 120 and from the index module 120 to the transfer module 140. Similarly, similarly, the second load lock 130b may also perform both the roles of transferring the semiconductor substrates from the transfer module 140 to the index module 120 and from the index module 120 to the transfer module 140.

The load lock chambers 130 may be loaded or unloaded with the semiconductor substrates by a substrate transfer robot 140b of the transfer module 140. The load lock chambers 130 may also be loaded or unloaded with the semiconductor substrates by the substrate transfer robot 120b of the index module 120.

As previously explained, the substrate transfer robot 120b may be provided within the index module 120, and as will be described later, the substrate transfer robot 140b may be provided within the transfer module 140. The substrate transfer robot 120b provided within the index module 120 is defined as the first transfer robot, and the substrate transfer robot 140b provided within the transfer module 140 is defined as the second transfer robot, distinguishing between the two substrate transfer robots 120b and 140b.

The load lock chambers 130 may maintain pressure while changing their internal environment between a vacuum environment and an atmospheric pressure environment using gate valves. In this manner, the load lock chambers 130 can prevent changes in the internal pressure state of the transfer module 140.

Specifically, when the semiconductor substrates are loaded or unloaded by the substrate transfer robot 140b of the transfer module 140, the load lock chambers 130 may create an internal environment that is the same as (or similar to) the vacuum environment of the transfer module 140. Similarly, when the semiconductor substrates are loaded or unloaded by the substrate transfer robot 120b of the index module 120, the load lock chambers 130 may create an internal environment that is the same as (or similar to) the atmospheric pressure environment of the index module 120.

The transfer module 140 interfaces the transfer of the semiconductor substrates between the load lock chambers 130 and the process chambers 150. To this end, the transfer module 140 may be equipped with the substrate transfer robot 140b within a module housing 140a. The substrate transfer robot 140b may operate in a vacuum environment, and at least one substrate transfer robot 140b may be provided within the module housing 140a.

The substrate transfer robot 140b transfers untreated substrates from the load lock chambers 130 to the process chambers 150, or transfers treated substrates from the process chambers 150 to the load lock chambers 130. For this purpose, sides of the transfer module 140 may be connected to the load lock chambers 130 and the process chambers 150. Meanwhile, the substrate transfer robot 140b may be provided to be freely movable.

The process chambers 150 treats (or processes) the semiconductor substrates. A plurality of process chambers 150 may be arranged around the transfer module 140. In this case, the process chambers 150 receive the semiconductor substrates from the transfer module 140, treat the received semiconductor substrates, and then provide the treated semiconductor substrates back to the transfer module 140.

The process chambers 150 may be cylindrical in shape. The process chambers 150 may be formed of alumite with anodized surfaces may be hermetically sealed on the inside. Meanwhile, the process chambers 150 may also be formed in various shapes other than a cylindrical shape.

The semiconductor manufacturing equipment 100 may be formed to have a cluster platform structure. In this case, the process chambers 150 may be arranged in a cluster manner with respect to the transfer module 140, and the load lock chambers 130, i.e., the first and second load lock chambers 130a and 130b, may be arranged in the first direction 10.

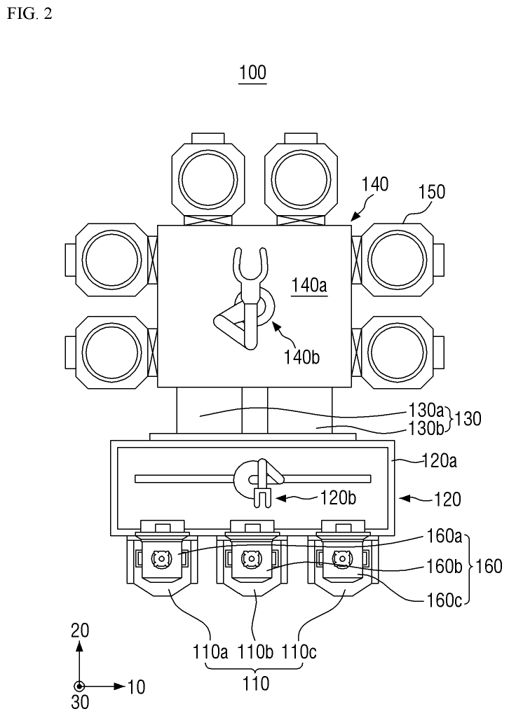

However, the present disclosure is not limited to this. Alternatively, referring to FIG. 2, the semiconductor manufacturing equipment 100 may be formed to have a quad platform structure. In this case, the process chambers 150 may be arranged in a quad manner with respect to the transfer module 140. FIG. 2 is a second exemplary schematic view illustrating the internal configuration of the semiconductor manufacturing equipment including the substrate treating apparatus that performs heat treatment on a semiconductor substrate.

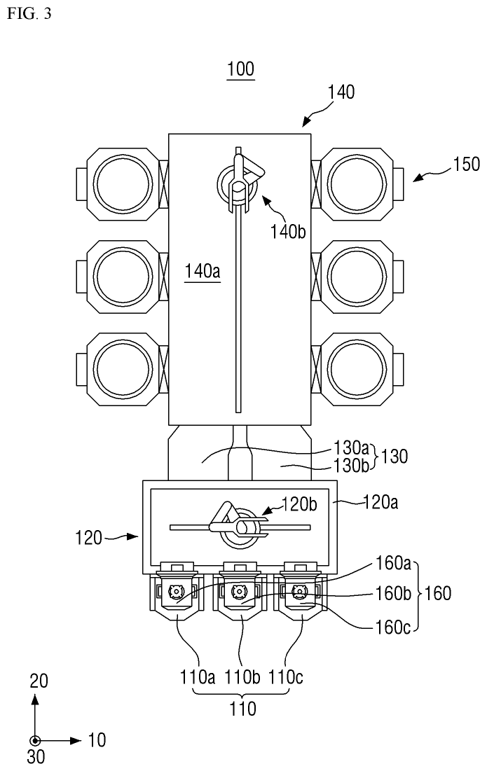

Yet alternatively, referring to FIG. 3, the semiconductor manufacturing equipment 100 may be formed to have an in-line platform structure, as illustrated in FIG. 1. In this case, the process chambers 150 may be arranged in an in-line manner with respect to the transfer module 140, and two different process chambers 150 may be arranged in series on either side of the transfer module 140 to correspond to each other. FIG. 3 is a third exemplary schematic view illustrating the internal configuration of the semiconductor manufacturing equipment including the substrate treating apparatus that performs heat treatment on a semiconductor substrate.

Although not explicitly illustrated in FIGS. 1 through 3, the semiconductor manufacturing equipment 100 may further include a control device. The control device controls the overall operations of the components of the semiconductor manufacturing equipment 100. For example, the control device may control substrate insertion and withdrawal performed by the substrate transfer robot 120b of the index module 120 and the substrate transfer robot 140b of the transfer module 140 and may also control substrate processing in the processing chambers 150.

The control device may include: a process controller, which consists of a microprocessor (or a computer) that executes the control of the semiconductor manufacturing equipment 100; a user interface, which includes a keyboard for an operator to input commands and manage the semiconductor manufacturing equipment 100 and a display to visualize the operating status of the semiconductor manufacturing equipment 100; and a memory unit, which stores control programs for executing processes under the control of the process controller or programs (or processing recipes) for executing processes in the semiconductor manufacturing equipment 100 based on various data and processing conditions. The user interface and the memory unit may be connected to the process controller. The processing recipes may be stored on a storage medium within the memory unit, and the storage medium may be a hard disk, a removable disc such as a compact disc read-only memory (CD-ROM) or a digital versatile disc (DVD), or a semiconductor memory such as a flash memory.

The process chambers 150, which are provided within the semiconductor manufacturing equipment 100, i.e., substrate treating apparatuses, will hereinafter be described. The substrate treating apparatuses may perform heat treatment on substrates.

As previously mentioned, the semiconductor manufacturing equipment 100 may include a plurality of process chambers 150, and these multiple process chambers 150 can be arranged in an inline fashion relative to the transfer module 140. In this case, process chambers 150 of different types may form corresponding relationships and may be arranged in rows on both sides of the transfer module 140. A process chamber 150 of one type may be a substrate treating apparatus performing heat treatment on substrates, while a process chamber 150 of another type may be a substrate treating apparatus performing a development process on substrates.

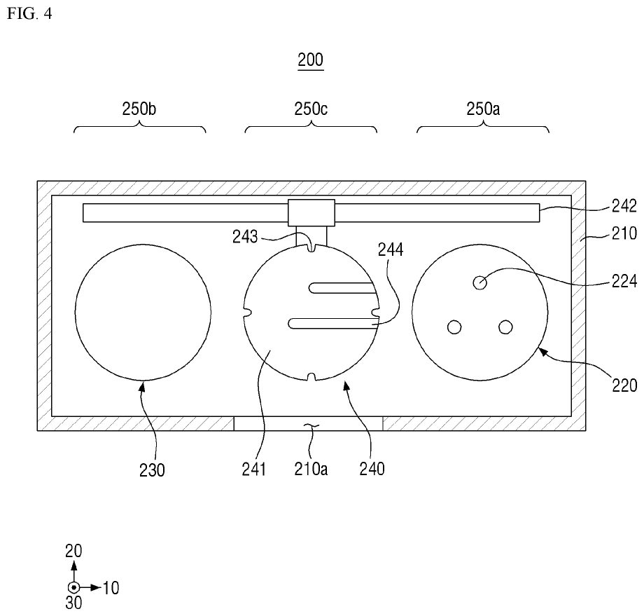

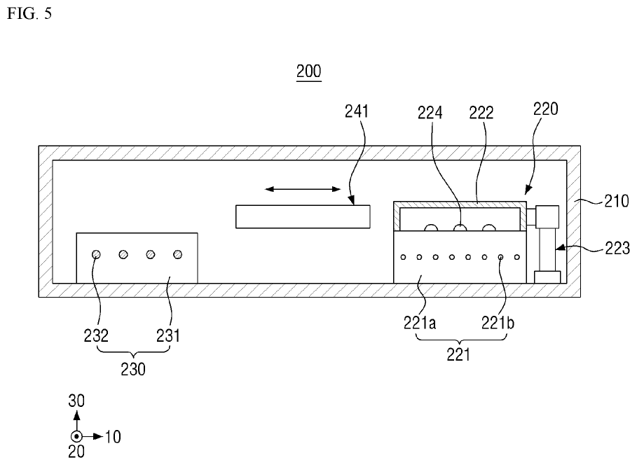

FIG. 4 is a plan view illustrating the internal configuration of a substrate treating apparatus that performs heat treatment on a semiconductor substrate. FIG. 5 is a cross-sectional view of the substrate treating apparatus that performs heat treatment on a semiconductor substrate.

Referring to FIGS. 4 and 5, a substrate treating apparatus 200 may be configured to include a chamber housing 210, a heating unit 220, a cooling unit 230, and a transfer unit 240.

The substrate treating apparatus 200 is an apparatus for heating and cooling a substrate (e.g., a wafer). When performing a photolithography process on a substrate, the substrate treating apparatus 200 may heat and cool the substrate. The substrate treating apparatus 200 may be provided as, for example, a bake chamber performing a bake process.

The photolithography process may include a photoresist (PR) coating process, an exposure process, a development process, and a bake process. In this case, the substrate treating apparatus 200 may heat and/or cool a substrate before or after the PR coating process. Alternatively, the substrate treating apparatus 200 may heat and/or cool a substrate before or after the exposure process. Yet alternatively, the substrate treating apparatus 200 may heat and/or cool a substrate before or after the development process.

The chamber housing 210 provides space for treating a substrate. The heating unit 220, the cooling unit 230, and the transfer unit 240 may be installed within the chamber housing 210 to enable heating and cooling for a substrate.

An entry port 210a, through which a substrate enters the chamber housing 210, may be formed on a sidewall of the chamber housing 210. At least one entry port 210a may be provided in the chamber housing 210. The entry port 210a may be always kept open. Alternatively, although not illustrated in FIG. 4, the entry port 210a may be provided with a door for opening and closing the entry port 210a.

The internal space of the chamber housing 210 may be divided into three areas: a heating area 250a, a cooling area 250b, and a buffer area 250c. Here, the heating area 250a refers to the area where the heating unit 220 is located, and the cooling area 250b refers to the area where the cooling unit 230 is located. The heating area 250a may be provided with the same width as or a greater width than the heating unit 220. Similarly, the cooling area 250b may be provided with the same width as or a greater width than the cooling unit 230.

The buffer area 250c refers to the area where a transfer plate 241 of the transfer unit 240 is located. The buffer area 250c may be provided between the heating area 250a and the cooling area 250b. In this case, the buffer area 250c may prevent thermal interference between the heating unit 220 and the cooling unit 230 by keeping the heating unit 220 and the cooling unit 230 sufficiently separated. Similarly to the heating area 250a and the cooling area 250b, the buffer area 250c may be provided with the same width as or a greater width than the transfer plate 241.

When the heating unit 220, the cooling unit 230, and the transfer unit 240 are disposed on the heating area 250a, the cooling area 250b, and the buffer area 250c, respectively, within the chamber housing 210, the cooling unit 230, the transfer unit 240, and the heating unit 220 may be sequentially arranged in the first direction 10, but the present disclosure is not limited thereto. Alternatively, the heating unit 220, the transfer unit 240, and the cooling unit 230 may be sequentially arranged in the first direction 10.

The heating unit 220 heats the substrate. When the heating unit 220 heats the substrate, the heating unit 220 may supply gas to the substrate. For example, the heating unit 220 may supply a hexamethyldisilane gas, and the supply of this type of gas may enhance the adhesion of PR to the substrate.

The heating unit 220 may be configured to include a heating plate 221, a cover module 222, and a driving module 223.

The heating plate 221, which is also referred to as a hot plate, applies heat to the substrate. To this end, the heating plate 221 may include a body part 221a and heaters 221b.

The body part 221a supports the substrate when applying heat to the substrate. The body part 221a may be formed to have the same diameter as or a greater diameter than the substrate.

The body part 221a may be formed of a material with excellent heat resistance or fire resistance. For example, the body part 221a may be formed of ceramics such as aluminum oxide (Al₂O₃) or aluminum nitride (AlN).

Meanwhile, although not illustrated in FIGS. 4 and 5, the body part 221a may include a plurality of vacuum holes that are formed to penetrate in the vertical direction (e.g., the third direction 30). Here, the vacuum holes may create a vacuum pressure to secure the substrate when applying heat to the substrate.

Meanwhile, although not explicitly illustrated in FIGS. 4 and 5, the body part 221a may be divided into an upper plate and a lower plate. In this case, the substrate may be mounted on the upper plate, and the heaters 221b may be installed within the lower plate.

The heaters 221b applies heat to the substrate on the body part 221a. A plurality of heaters 221b may be installed within the body part 221a. The heaters 221b may be configured as heating resistors (for example, heating elements) through which a current is applied. However, the heaters 221b may be of any other form as long as they can effectively apply heat to the substrate on the body part 221a.

The cover module 222 is formed to cover the top of the heating plate 221 when the heating plate 221 heats the substrate. The cover module 222 may move in the vertical direction (or the third direction 30) under the control of the driving module 223 to open and close the top of the heating plate 221.

The driving module 223 is for moving the cover module 222 in the vertical direction (or the third direction 30). When the substrate is securely positioned on the top of the heating plate 221 for heat treatment, the driving module 223 may move the cover module 222 in a downward direction toward the chamber housing 210 to completely cover the top of the heating plate 221. Also, once the heat treatment of the substrate is complete, the driving module 223 may move the cover module 222 in an upward direction, thereby exposing the top of the heating plate 221 to allow the transfer unit 240 to move the substrate to the cooling unit 230.

The cooling unit 230 cools the substrate that has been heated by the heating unit 220. For this purpose, the cooling unit 230 may be configured to include a cooling plate 231 and cooling elements 232.

When high-temperature heat is applied to the substrate via the heating unit 220, warpage of the substrate may occur. The cooling unit 230 may restore the substrate to its original state by cooling the substrate down to an appropriate temperature.

The cooling elements 232 are formed within the cooling plate 231. The cooling elements 232 may be provided as flow paths through which a cooling fluid flows.

The transfer unit 240 moves the substrate to either the heating unit 220 or the cooling unit 230. For this purpose, the transfer unit 240 may have a hand coupled with a transfer plate 241 at its end and may move the transfer plate 241 along a guide rail 242 toward where the heating unit 220 or the cooling unit 230 is located.

The transfer plate 241, which is disc-shaped, may be formed to have a diameter corresponding to the substrate. The transfer plate 241 may include a plurality of notches 243, which are formed along the edge of the transfer plate 241, and a plurality of guide grooves 244, which are on the top surface of the transfer plate 241 and have a slit shape.

The guide grooves 244 may be formed to extend from the end of the transfer plate 241 toward the center of the transfer plate 241. The guide grooves 244 may be spaced apart in the same direction (or the first direction 10). The guide grooves 244 may prevent interference between the transfer plate 241 and lift pins 224 when the substrate is transferred between the transfer plate 241 and the heating unit 220.

The substrate is heated when it is directly placed on the heating plate 221 and is cooled when the transfer plate 241 where the substrate is placed comes into contact with the cooling plate 231. To facilitate efficient heat transfer between the cooling plate 231 and the substrate, the transfer plate 241 may be formed of a material with excellent thermal conductivity (e.g., a metal).

Meanwhile, although not illustrated in FIGS. 4 and 5, the transfer unit 240 may receive the substrate from an externally installed substrate transfer robot through the inlet 210a of the chamber housing 210.

The lift pins 224 have a free-fall structure and serve the role of lifting up or down the substrate on the heating plate 221. After receiving the substrate from the transfer unit 240, the lift pins 224 may descend to secure the substrate on the heating plate 221 for a baking process. Once the baking process is complete, the lift pins 224 may ascend to transfer the substrate back to the transfer unit 240. The lift pins 224 may be formed to penetrate the heating plate 221 in the vertical direction (or the third direction 30).

The lift pins 224, like the body part 221a, may be formed of a material with excellent heat resistance. In this case, the lift pins 224 may be formed of the same metal as the body part 221a, but alternatively, the lift pins 224 and the body part 221a may also be formed of different metals.

For example, the lift pins 224 may be driven using a linear motor (LM) guide system and may be controlled by a plurality of cylinders connected to the LM guide system. The LM guide system has the advantage of being able to cope with high temperatures and vibrations.

Meanwhile, a plurality of lift pins 224 may be installed on the heating plate 221 to stably support the substrate when lifting up the substrate from the heating plate 221. For example, as illustrated in FIGS. 4 and 5, three lift pins 224 may be installed.

As mentioned earlier, the substrate treating apparatus 200 may control the internal airflow within the chamber housing 210 to enable heat treatment for the substrate. In this case, internal airflow control may be performed under the control of the control device. This will hereinafter be described.

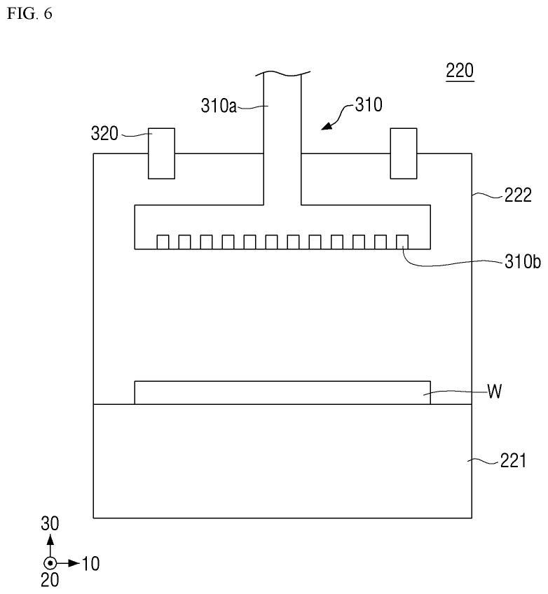

FIG. 6 is a first exemplary schematic view illustrating the internal configuration of a heating unit in the substrate treating apparatus for internal airflow control. Referring to FIG. 6, the heating unit 220 may be configured to include the heating plate 221, the cover module 222, an intake module 310, and an exhaust module 320.

The heating plate 221 and the cover module 222 have already been described above with reference to FIGS. 4 and 5, and thus, detailed descriptions thereof will be omitted. For convenience, the driving module 223 is not illustrated in FIG. 6, and the movement of the cover module 222 is not limited to being controlled by the driving module 223. In a case where the cover module 222 is moved by a different method, the driving module 223 may not be provided within the heating unit 220. Furthermore, for convenience, the lift pins 224 are also not illustrated in FIG. 6, and the lift pins 224 may not be provided on the heating plate 221.

Meanwhile, in the examples of FIGS. 4 and 5, the heating unit 220 and the cooling unit 230 may be provided together within the chamber housing 210, but the present disclosure is not limited thereto. Alternatively, the heating unit 220 may be provided alone in a separate chamber housing from the cooling unit 230.

The intake module 310 suctions external air and supplies it to the internal space of the heating unit 220. The intake module 310 may include an air inlet duct 310a, which connects with the external environment, and a plurality of air exhaust holes 310b, which are arranged within the internal space of the heating unit 220.

The exhaust module 320 discharges air that has been introduced into the internal space of the heating unit 220 to the external environment. The exhaust module 320 may connect with the external environment through the cover module 222. Alternatively, when the heating unit 220 is provided in a separate chamber housing, the exhaust module 320 may connect with the external environment through the corresponding chamber housing.

At least one intake module 310 and at least one exhaust module 320 may be provided within the heating unit 220. For example, the intake module 310 may be equipped with one air inlet duct 310a, and two exhaust modules 320 may be provided on both sides of the air inlet duct 310a. However, the present disclosure is not limited to this example.

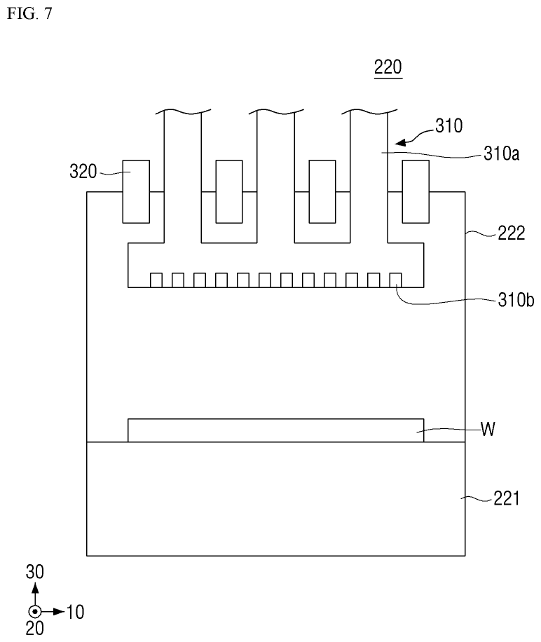

Alternatively, referring to FIG. 7, the intake module 310 may include three air inlet ducts 310a, and four exhaust modules 320 may be provided between three air inlet ducts 310a or on both sides of the array of the three air inlet ducts 310a. FIG. 7 is a second exemplary schematic view illustrating the internal structure of the heating unit in the substrate treating apparatus for internal airflow control.

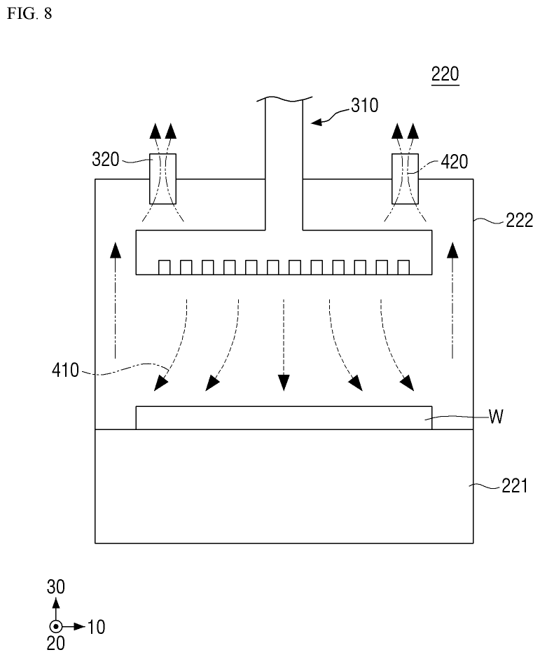

The amount of air 410 supplied to the internal space of the heating unit 220 through the intake module 310 and the amount of air 420 discharged from the internal space of the heating unit 220 through the exhaust module 320 may be independently controlled, thereby allowing for the adjustment of the thickness of an insulating film formed on a semiconductor substrate W. In other words, internal airflow control not only enables thickness (THK) adjustment between the center and edge areas of the semiconductor substrate W, but also improves thickness asymmetry. The intake module 310 may adjust the amount of air 410 supplied to the internal space of the heating unit 220 under the control of the control device, and similarly, the exhaust module 320 may adjust the amount of air 420 discharged from the internal space of the heating unit 220 under the control of the control device. FIG. 8 is a first exemplary schematic view illustrating an internal airflow control method of the heating unit of the substrate treating apparatus.

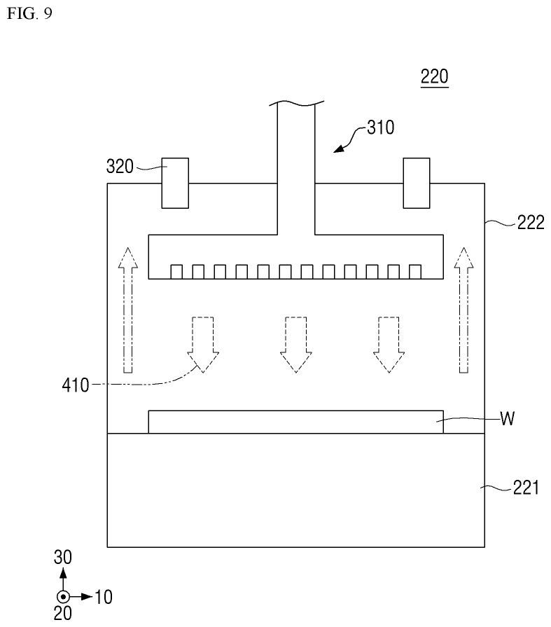

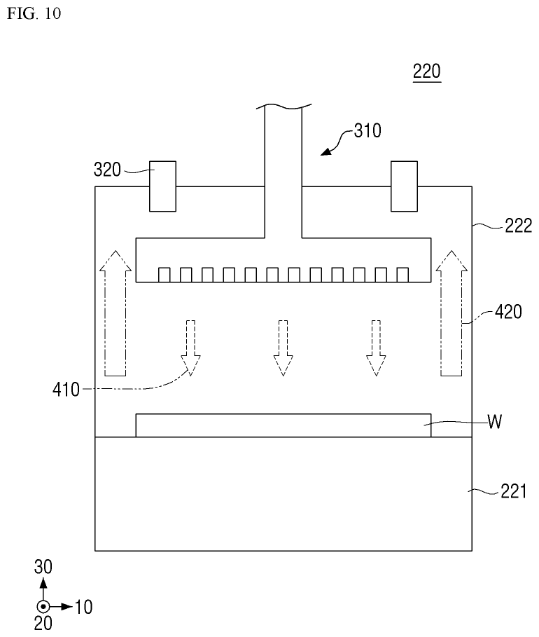

The amount of air 410 supplied to the internal space of the heating unit 220 through the intake module 310 may differ from the amount of air 420 discharged from the internal space of the heating unit 220 through the exhaust module 320. Specifically, referring to FIG. 9, the amount of air 410 supplied to the internal space of the heating unit 220 through the intake module 310 may be greater than the amount of air 420 discharged from the internal space of the heating unit 220 through the exhaust module 320. Alternatively, referring to FIG. 10, the amount of air 410 supplied to the internal space of the heating unit 220 through the intake module 310 may be less than the amount of air 420 discharged from the internal space of the heating unit 220 through the exhaust module 320. FIG. 9 is a second exemplary schematic view illustrating the internal airflow control method of the heating unit of the substrate treating apparatus. FIG. 10 is a third exemplary schematic view illustrating the internal airflow control method of the heating unit of the substrate treating apparatus.

When there is a need to adjust the thickness of the insulation film formed on the semiconductor substrate W, the amount of air 410 supplied to the internal space of the heating unit 220 through the intake module 310 may be controlled to be greater or less than the amount of air 420 discharged from the internal space of the heating unit 220 through the exhaust module 320. For example, to form a thin insulation film on the semiconductor substrate W, the amount of air 410 supplied through the intake module 310 may be controlled to be greater than the amount of air 420 discharged through the exhaust module 320. Conversely, to form a thick insulation film on the semiconductor substrate W, the amount of air 410 supplied through the intake module 310 may be controlled to be less than the amount of air 420 discharged through the exhaust module 320.

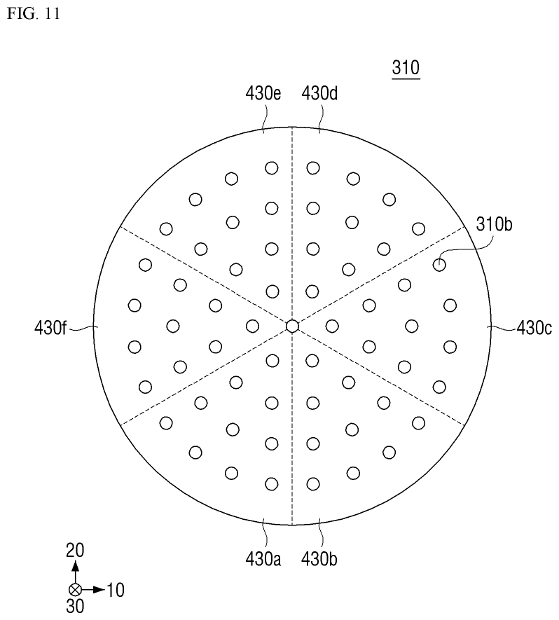

A plurality of air exhaust holes 310b may be installed on the lower surface of the intake module 310 and may be positioned within the internal space of the heating unit 220. The air exhaust holes 310b may be divided by area on the lower surface of the intake module 310. Specifically, the lower surface of the intake module 310 may be radially divided into a plurality of areas, the air exhaust holes 310b may be distributed between the plurality of areas. For example, referring to FIG. 11, the air exhaust holes 310b may be distributed among six areas 430a, 430b, 430c, 430d, 430e, and 430f, which are obtained by radially dividing the lower surface of the intake module 310.

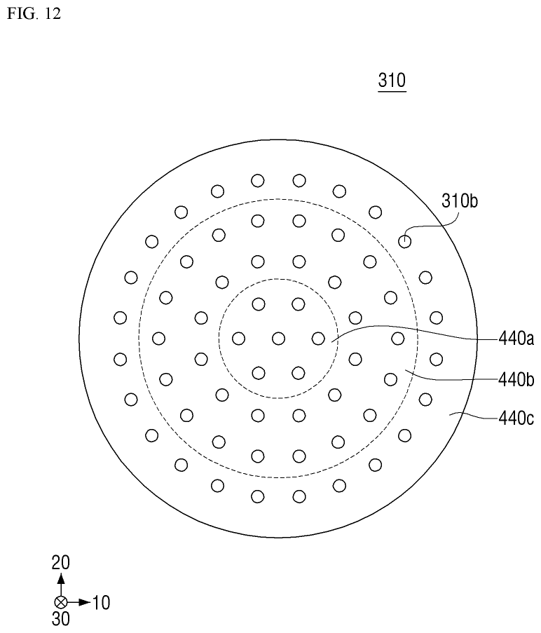

However, the present disclosure is not limited to this. Alternatively, referring to FIG. 12, the air exhaust holes 310b may be divided based on their distance from the center of the lower surface of the intake module 310. For example, referring to FIG. 12, the air exhaust holes 310b may be distributed among three areas 440a, 440b, and 440c, which are classified by their distance from the center of the intake module 310.

When the air exhaust holes 310b are formed as illustrated in FIG. 11 or 12, the amount of air supplied to the internal space of the heating unit 220 through the intake module 310 may be independently controlled for different areas of the semiconductor substrate W. FIG. 11 is a first exemplary schematic view illustrating the arrangement structure of the air exhaust holes of the intake module in the heating unit. FIG. 12 is a second exemplary schematic view illustrating the arrangement structure of the air exhaust holes of the intake module in the heating unit.

When the air exhaust holes 310b are arranged across areas of the intake module 310 that are divided radially or based on their distance from the center of the lower surface of the intake module 310, the amount of air supplied to the internal space of the heating unit 220 through the intake module 310 may vary for different areas of the semiconductor substrate W. For example, to adjust the thickness of an insulating film between the center and edge areas of the semiconductor substrate W, the air supplied to each area of the semiconductor substrate W may be controlled differently using the air exhaust holes 310b of FIG. 12. Additionally, to address asymmetry and adjust the thickness of an insulation film between the left and right areas of the semiconductor substrate W, the air supplied to each area of the semiconductor substrate W may be controlled differently using the air exhaust holes 310b of FIG. 11.

By controlling the internal airflow differently for different areas, the process control capability can be enhanced, and the left-right asymmetry of the thickness of an insulating film can be improved. That is, by radially dividing the airflow entering and exiting the internal space of the heating unit 220 and controlling it differently for different areas, fine thickness adjustment is enabled, and any left-right thickness asymmetry can be prevented.

Meanwhile, the air exhaust holes 310b may be divided not only radially but also based on their distance from the center of the intake module 310. In this case, the thickness of the insulating film formed on the semiconductor substrate W can be controlled not only between the center and edge areas of the semiconductor substrate W, but also between the left and right areas of the semiconductor substrate W, at the same time.

The exhaust module 320 may be opened and closed. When there are a plurality of exhaust modules (320a, 320b, . . . , 320k, . . . , and 320n), the exhaust modules (320a, 320b, . . . , 320k, . . . , and 320n) may be independently opened and closed. Consequently, the amount of air discharged from the internal space of the heating unit 220 to the external environment may be adjusted through the opening and closing of the plurality of exhaust modules 320. The opening and closing of the exhaust modules (320a, 320b, . . . , 320k, . . . , and 320n) may be performed under the control of the control device.

When the amount of air supplied to the internal space of the heating unit 220 through the intake module 310 remains constant, the amount of air supplied to the internal space of the heating unit 220 through the intake module 310 may be greater or less than the amount of air discharged from the internal space of the heating unit 220 through the plurality of exhaust modules 320, depending on the opening and closing of the plurality of exhaust modules 320.

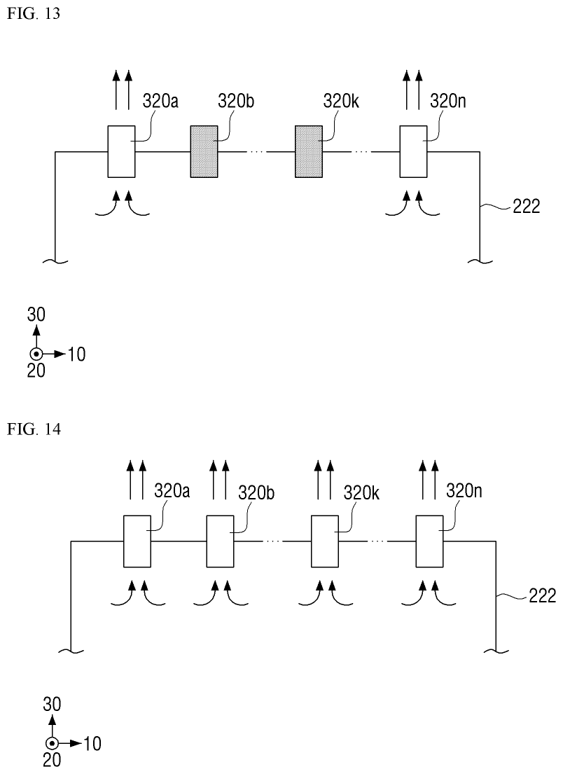

For example, if the amount of air supplied to the internal space of the heating unit 220 through the intake module 310 is greater than the amount of air discharged from the internal space of the heating unit 220 through the exhaust modules (320a, 320b, . . . , 320k, . . . , and 320n), some of the exhaust modules (320a, 320b, . . . , 320k, . . . , and 320n), for example, the exhaust modules 320a and 320n, may be opened to allow external ventilation, while others exhaust modules 320b and 320k may remain closed. FIG. 13 is a first exemplary schematic view illustrating a control method for exhaust modules within the heating unit.

Conversely, if the amount of air supplied to the internal space of the heating unit 220 through the intake module 310 is less than the amount of air discharged from the internal space of the heating unit 220 through the exhaust modules (320a, 320b, . . . , 320k, . . . , and 320n), all the exhaust modules 320a, 320b, . . . , 320k, . . . , and 320n) may be opened to allow external ventilation. FIG. 14 is a second exemplary schematic view illustrating the control method for the exhaust modules in the heating unit.

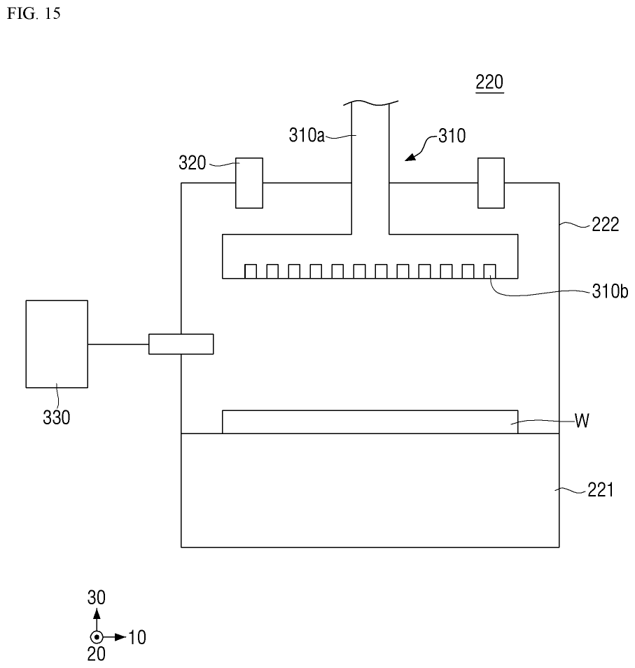

Referring to FIG. 15, the heating unit 220 may further include a gas concentration control module 330. The gas concentration control module 330 may adjust the concentration of a nitrogen (N₂) component in the internal space of the heating unit 220. Alternatively, the gas concentration control module 330 may adjust the concentration of an oxygen (O₂) component in the internal space of the heating unit 220. FIG. 15 is an exemplary schematic view illustrating the gas concentration control module of the substrate treating apparatus.

The gas concentration control module 330 may adjust the gas concentration in the internal space of the heating unit 220 based on gas concentration measurement result data, i.e., concentration feedback information. For example, the gas concentration control module 330 may adjust the ratio between nitrogen and oxygen components based on concentration measurement result data for nitrogen. By adjusting the ratio of the nitrogen and oxygen components, the gas concentration control module 330 may manage the oxygen saturation and may thereby control the etch rate for the semiconductor substrate W.

When controlling the etch rate for the semiconductor substrate W through the adjustment of the ratio between the nitrogen and oxygen components, the gas concentration control module 330 may increase the concentration of nitrogen in the internal space of the heating unit 220 to enhance the etch rate for the semiconductor substrate W. Additionally, the gas concentration control module 330 may decrease the concentration of nitrogen in the internal space of the heating unit 220 to reduce the etch rate for the semiconductor substrate W.

The present disclosure relates to a uniform thickness adjustment method during the formation of an insulating film that includes a H—SOH process. Furthermore, the present disclosure relates to a method for adjusting etch rate with oxygen saturation by using N₂. The key features of the present disclosure are as follows.

First, insulation film thickness variations can be controlled by dividing the flow within a chamber and controlling it differently for different areas.

Second, oxygen saturation can be adjusted through the adjustment of the nitrogen-to-oxygen ratio, enabling the adjustment of etch rate.

Third, oxygen saturation can also be controlled differently for different areas, enabling the control of etch rate variations.

The present disclosure have been described above with reference to the accompanying drawings, but the present disclosure is not limited thereto and may be implemented in various different forms. It will be understood that the present disclosure can be implemented in other specific forms without changing the technical concept or gist of the present disclosure. Therefore, it should be understood that the embodiments set forth herein are illustrative in all respects and not limiting.

What is claimed is:

1. A substrate treating apparatus comprising:
a heating plate heating a substrate;
a cover module covering the top of the heating plate;
an intake module introducing external air into an internal space formed by the cover module; and
an exhaust module discharging the air introduced into the internal space to the outside,
wherein at least one of the intake module and the exhaust module controls airflow in the internal space.

2. The substrate treating apparatus of claim 1, wherein
the intake module controls an inflow amount of air,
the exhaust module controls an outflow amount of air, and
the airflow in the internal space is controlled based on the inflow and outflow amounts of air.

3. The substrate treating apparatus of claim 2, wherein the intake module controls the inflow amount of air differently from the outflow amount of air.

4. The substrate treating apparatus of claim 2, wherein the intake module controls the inflow amount of air to be greater than the outflow amount of air.

5. The substrate treating apparatus of claim 2, wherein the intake module controls the inflow amount of air to be less than the outflow amount of air.

6. The substrate treating apparatus of claim 2, wherein the intake module controls the inflow amount of air for each area of the substrate.

7. The substrate treating apparatus of claim 1, wherein at least one of the intake module and the exhaust module controls the airflow in the internal space when adjusting a thickness of an insulating film formed on the substrate.

8. The substrate treating apparatus of claim 1, wherein the intake module and the exhaust module control inflow and outflow amounts of air independently.

9. The substrate treating apparatus of claim 1, wherein
the exhaust module includes a plurality of air exhaust holes, which guide external air into the internal space,
the air exhaust holes are divided by area.

10. The substrate treating apparatus of claim 9, wherein the air exhaust holes are divided among a plurality of areas that are divided either radially or based on their distance from a center.

11. The substrate treating apparatus of claim 9, wherein the intake module controls an inflow amount of air differently for different areas of the substrate, using the air exhaust holes.

12. The substrate treating apparatus of claim 1, wherein
a plurality of exhaust modules are provided, and
the plurality of exhaust modules are independently opened or closed.

13. The substrate treating apparatus of claim 1, further comprising:
a gas concentration control module controlling a gas concentration in the internal space.

14. The substrate treating apparatus of claim 13, wherein the gas concentration control module controls a ratio of first and second gases based on concentration measurement result data for the first gas.

15. The substrate treating apparatus of claim 14, wherein the gas concentration control module uses a gas containing a nitrogen component as the first gas and a gas containing an oxygen component as the second gas.

16. The substrate treating apparatus of claim 13, wherein the gas concentration control module controls the gas concentration in the internal space when controlling etch rate for the substrate.

17. Semiconductor manufacturing equipment comprising:
a plurality of process chambers of different types,
wherein
the plurality of process chambers include a process chamber of one type, which is a first substrate treating apparatus that performs heat treatment on a substrate and a process chamber of another type, which is a second substrate treating apparatus that performs a development process on the substrate,
the first substrate treating apparatus includes a heating plate heating a substrate, a cover module covering the top of the heating plate, an intake module introducing external air into an internal space formed by the cover module, and an exhaust module discharging the air introduced into the internal space to the outside, and
at least one of the intake module and the exhaust module controls airflow in the internal space.

18. The semiconductor manufacturing equipment of claim 17, wherein the first substrate treating apparatus further includes a cooling unit including a cooling plate and cooling the substrate and a transfer unit transferring the substrate between the heating plate and the cooling plate.

19. The semiconductor manufacturing equipment of claim 17, wherein
the intake module controls an inflow amount of air,
the exhaust module controls an outflow amount of air, and
the intake module and the exhaust module control the airflow in the internal space by controlling the inflow and outflow amounts of air independently.

20. A substrate treating apparatus comprising:
a heating plate heating a substrate;
a cover module covering the top of the heating plate;
an intake module introducing external air into an internal space formed by the cover module;
an exhaust module discharging the air introduced into the internal space to the outside; and
a gas concentration control module controlling a gas concentration in the internal space,
wherein
the intake module controls an inflow amount of air,
the exhaust module controls an outflow amount of air,
the intake module and the exhaust module control airflow in the internal space by controlling the inflow and outflow amounts of air independently,
the intake module and the exhaust module control the airflow in the internal space when adjusting a thickness of an insulating film formed on the substrate, and
the gas concentration control module controls the gas concentration in the internal space when controlling etch rate for the substrate.
